(19) United States
(12) Patent Application Publication
(10) Pub. No.: US 2015/0170872 A1
(43) Pub. Date: Jun. 18, 2015

(54) SAMPLE HOLDER FOR ELECTRON MICROSCOPY

(71) Applicant: Danmarks Tekniske Universitet, Lyngby (DK)

(72) Inventors: Filippo CAVALCA, Copenhagen (DK); Thomas Willum HANSEN, Greve (DK); Christian Danvad DAMSGAARD, Farum (DK); Jakob Birkedal WAGNER, Soeborg (DK); Thomas PEDERSEN, Valby (DK); Ole HANSEN, Hoersholm (DK); Christoph LANGHAMMER, Gothenburg (SE)

(73) Assignee: DANMARKS TEKNISKE UNIVERSITET, Lyngby (DK)

(21) Appl. No.: 14/105,752

(22) Filed: Dec. 13, 2013

(51) Int. Cl. H01J 37/20

(52) U.S. Cl. CPC H01J 37/20; H01J 2237/2001

(57) ABSTRACT

The present invention relates to an assembly for holding a sample during characterisation of said sample in an electron microscope, the assembly comprising a feedthrough, a middle portion and a tip portion, wherein the tip portion comprises a frame structure, a light handling system attached thereto, and a temperature controlling arrangement also attached to the frame structure. The present invention further relates to a tip portion for the assembly for holding the sample.

### FIELD OF THE INVENTION

The present invention relates to a sample holder assembly for use in relation to electron microscopy, such as transmission electron microscopy (TEM) or environmental transmission electron microscopy (ETEM). In particular, the present invention relates to a sample holder with an integrated light handling system and a heating arrangement.

### BACKGROUND OF THE INVENTION

The concept of light handling in electron microscopes has been approached by several research groups. A single light guide has been implemented successfully for light illumination or for light output. However, the simultaneous implementation of a light source and an optical readout system was only recently proposed, and yet no results are reported in the literature.

It may be seen as an object of embodiments of the present invention to provide a sample holder with integrated light handling.

It may be seen as a further object of embodiments of the present invention to provide a sample holder where light may be guided to the sample in a well-defined manner.

It may be seen as a still further object of embodiments of the present invention to provide a sample holder where light may be collected and guided away from the sample in a well-defined manner.

### DESCRIPTION OF THE INVENTION

The above-mentioned objects are complied with by providing, in a first aspect, an assembly for holding a sample during characterisation of said sample in an electron microscope, the assembly comprising a feedthrough, a middle portion and a tip portion, wherein the tip portion comprises a frame structure, a light handling system attached to the frame structure, and a temperature controlling arrangement attached to the frame structure. The middle and the tip portions of the assembly are adapted to be positioned within a vacuum chamber of the electron microscope during characterisation.

It is advantageous that the present invention allows that typical TEM and ETEM features may be further expanded by enabling experiments under light illumination on for example photocatalysts.

The feedthrough, the middle portion and the tip portion preferably form, in combination, an elongated structure adapted to be inserted into the vacuum chamber of an electron microscope.

The feedthrough and the middle portion allow that electrical and/or optical connections may be provided between the exterior of the vacuum chamber and the tip portion. Thus, electrical wires and/or optical fibres may connect the exterior of the vacuum chamber and the tip portion. Preferably, the middle portion takes the form of a hollow barrel so that wires and/or optical fibres may be hidden therein.

The light handling system may comprise a first light guiding element for providing light to the sample, and a second light guiding element for collecting light scattered off or reflected from the sample.

The light scattered off or reflected from the sample may be guided to for example a spectrometer positioned outside the vacuum chamber. The first and second light guiding elements may comprise first and second optical fibres, respectively, such as first and second multimode optical fibres.

The optical fibre used for illuminating the sample may be prepared by appropriate shaping of the exit end of the fibre. For example, the exit end may be a flat cleaved end or it may comprise a micro lens. Similarly, the optical fibre used for collecting light scattered off or reflected from the sample may be appropriately shaped in order to collect light in an optimal manner. Again, a flat cleaved end or a micro lens may be formed at the entry end of the collecting fibre.

The first and second optical fibres may be arranged in an essentially parallel manner along at least part of their lengths. The parallel arrangement of the first and second optical fibres is of particular relevance for the fibre ends closest to the sample to be investigated. To maintain these fibre ends at an essentially parallel arrangement the light handling system may further comprise a mirror chip arrangement for holding the respective end portions of the first and second optical fibres in a pair of V-shaped grooves.

In order to analyse a given sample the mirror chip arrangement may comprise respective reflective surfaces for directing emitted light from the first optical fibre towards the sample, and for directing light scattered off or reflected from the sample towards the second optical fibre. The direction of reflection may be 45° relative to mirror chip arrangement and 90° relative to the parallel fibre ends.

The frame structure may comprise a plurality of electrical contact elements. These electrical contact elements, which may be implemented as resilient contacts, may be used for establishing electrical contacts to the temperature controlling arrangement. Hence, the temperature controlling arrangement may comprise a heating element and a plurality electrical contact pads, where each of said plurality of electrical contact pads is adapted to form an electrical connection with an electrical contact element of the frame structure. Preferably, the heating element and the plurality of electrical contact pads form an integral part of the temperature controlling arrangement.

In a second aspect the present invention relates to a tip portion for an assembly for holding a sample during characterisation of said sample in an electron microscope, the tip portion comprising a frame structure, a light handling system attached to the frame structure, and a temperature controlling arrangement attached to the frame structure.

Similar to the first aspect the light handling system may comprise a first light guiding element for providing light to the sample, and a second light guiding element for collecting light scattered off or reflected from the sample. These first and second light guiding elements may comprise first and second optical fibres, respectively, such as first and second multimode optical fibres.

The ends of the first and second fibres being closest to the sample may be arranged in V-shaped grooves, said V-shaped grooves positioning the first and second optical fibres in an essentially parallel manner along at least part of their lengths. The V-shaped grooves may be provided in a mirror chip arrangement similar to the one disclosed in relation to the first aspect. Also, the mirror chip arrangement may comprise respective reflective surfaces for directing emitted light from the first optical fibre towards the sample, and for directing light scattered off or reflected from the sample towards the second optical fibre. Similar to the first aspect, the direction of reflection may be 45° relative to mirror chip arrangement and 90° relative to the parallel fibre ends.

### DESCRIPTION OF THE DRAWINGS

The present invention will now be described in further details with reference to the accompanying figures, where

FIG. 1 shows a sample holder according to the present invention,

FIG. 2 shows a tip portion for the sample holder,

FIG. 3 shows a light handling system, and

FIG. 4 shows a heating arrangement.

While the invention is susceptible to various modifications and alternative forms, specific embodiments have been shown by way of examples in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

### DETAILED DESCRIPTION OF THE INVENTION

In its most general aspect the present invention relates to a sample holder for electron microscopy, said sample holder comprising an integrated light handling system and an integrated heating arrangement. The integrated light handling system ensures that light may be guided to and from the sample in situ and in a controlled manner. The integrated heating arrangement facilitates that the temperature of the sample may be controlled.

The sample holder according to the present invention is intended for holder samples to be in situ analysed in electron microscopes, such as TEM microscopes.

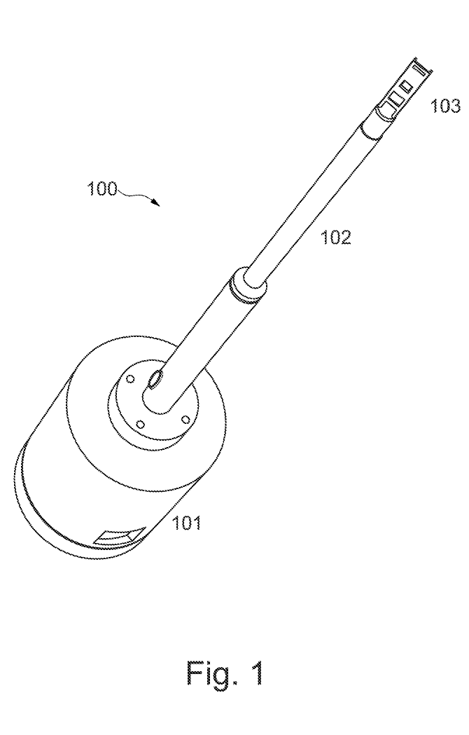

FIG. 1 shows a sample holder 100 according to the present invention comprising a bottom feedthrough 101, a hollow barrel 102 and a customized holder tip 102. The feedthrough 101 and the barrel 102 accommodate two fibres (not shown). The fibres are introduced via a hollow ¾″ national pipe thread (NPT) vacuum connector. This facilitates easier replacement of the fibres in case of failure.

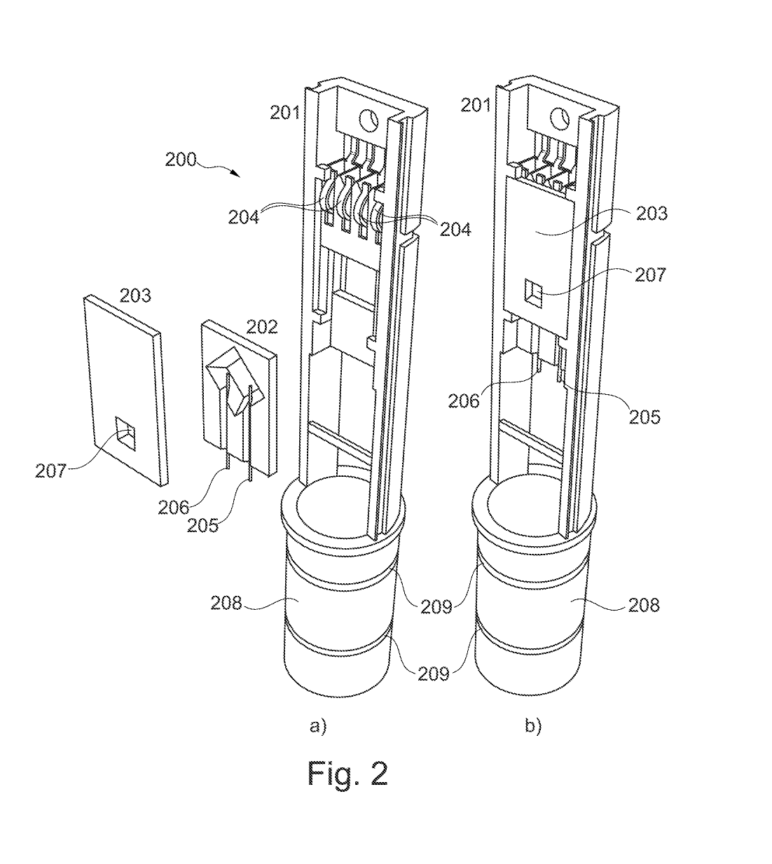

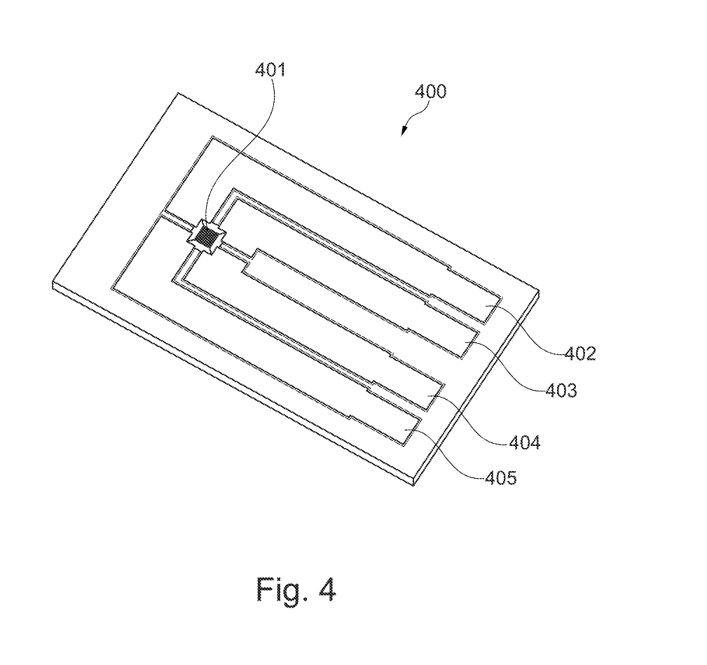

FIG. 2a shows an exploded view of the tip of the sample holder 200 according to the present invention. The tip is positioned on top of the hollow barrel 208. In FIG. 2a the tip is constituted by a frame structure 201, the light handling system 202 and the heating arrangement 203 are depicted. The frame structure 201 comprises a number of electrical contacts 204 (four in FIG. 2a) adapted to contact with associated contact pads on the heating arrangement 203, cf. FIG. 4. These contact pads are in electrical contact with the heating element 207, cf. FIG. 4. The light handling system 202 supports two optical fibres 205, 206.

One of the fibres is adapted to guide light to the sample whereas the other fibre is adapted to guide light away from the sample. Light to be provided to the sample may in principle be generated by any light source, such as a laser source or a broadband light source. Light captured and guided away from the sample may be led to any kind of analysing equipment, such as a spectrometer.

The light handling system further comprises a number of appropriately aligned reflective surfaces for illuminating the sample and collecting light from the sample in an effective manner. The light handling system will be disclosed in further details in connection with FIG. 2. The electrical contacts 204 are electrically connected to the outside of the electron microscope via the hollow barrel 208. O-rings (not shown) are to be positioned in the two grooves 209 for fixation purposes.

FIG. 2b shows the assembled sample holder comprising the frame structure, the light handling system and the heating arrangement in a sandwiched construction. The assembled sample holder, including a sample, is mounted in the vacuum chamber of the electron microscope which is then pumped to a desired pressure level.

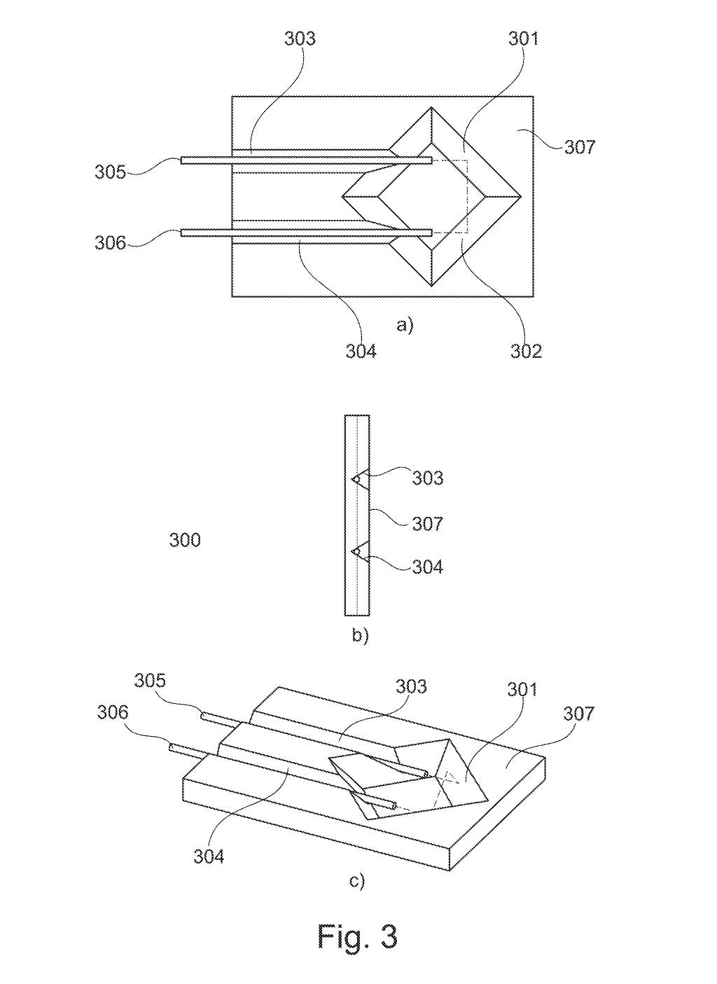

Referring now to FIG. 3 the light handling system 300 is shown. The light handling system 300 is formed as a rectangular mirror chip and it is adapted to be positioned within the holder tip. It contains two reflecting surfaces 301,302 at 45° to the chip surface and 90° with respect to one another. Two grooves 303,304 which lead to the reflection surfaces are arranged parallel to the long side of the chip and hold two optical fibres 305,306 in place.

This geometry allows light coming from one fibre 305 to be reflected out of plane at an angle of 45 with respect to the wafer surface and 90° with respect to the incoming light beam. This is illustrated by the dotted lines in FIGS. 3a and 3c. If a reflective surface is positioned parallel to the mirror chip, light would bounce off it and follow a path symmetric to the one described until it is captured in the second fibre 306.

Anisotropic KOH chemical etching is typically used to obtain crystallographically-defined planes at 54.7° with respect to the chip surface, which is evidently not suitable for the desired reflection geometry. Therefore, the chip was fabricated from a 500 μm thick silicon wafer via a non-conventional wet etching process using surfactant modified TMAH etching in order to achieve planes inclined at 45° to the silicon surface.

The mirror chip design and the choice of fibre were strongly entangled. A trade-off between maximization of the mirror surfaces and the total chip thickness had to be faced. Since the mirror surfaces 301,302 are tilted 45° with respect to the wafer surface 307, their width is calculated as \sqrt{2}t, where t is the wafer thickness. A larger reflecting surface would result in a thicker wafer, which would add up to the total device thickness. Two grooves were designed to accommodate the largest fibres available. Fibres with a 125 μm cladding diameter were chosen in order to sit in the etched chip recesses at half chip thickness. The light path of an axial light beam can be traced in the design software as a function of other dimensions. If symmetry is maintained across the longitudinal centreline, the position of the reflection vertex in the y and z axes depends on the spacing between the grooves. An inter-fibre distance of 1.40 mm was chosen, which corresponds to a 0.45 mm elevation of the reflection apex from the upper chip surface and a 0.70 mm displacement from the window centre.

Referring now to FIG. 4 a MEMS heater 400 hosting the Indirect Nano Plasmonic Sensing (INPS) sensor was designed to enable in situ heating and hold the sample on an electron transparent yet optically reflective surface for reflection Localized Surface Plasmon Resonance (LSPR) measurements. The chip shown in FIG. 4 was fabricated from a 350 μm thick silicon-on-oxide (SOI) wafer and consists of a silicon membrane 401 suspended on a squared opening in the silicon wafer. The membrane is connected via 4 arms to the chip, each leading to one electrical pad 402-405.

Still referring to FIG. 4 30 nm-thick silicon nitride (Si3N4) electron transparent viewing windows are etched in the membrane to allow for TEM investigation. The INPS sensors are patterned on top of this structure via shadow mask lithography and embedded in an extra layer of nitride. This extra dielectric layer is indispensable for insulation of the INPS sensor from the surrounding environment but adds to the total thickness within the viewing windows. Heaters can be produced without INPS sensors for conventional heating experiments, maintaining electron transparency at a maximum.

1. An assembly for holding a sample during characterisation of said sample in an electron microscope, the assembly comprising a feedthrough, a middle portion and a tip portion, wherein the tip portion comprises
a frame structure,
a light handling system attached to the frame structure, and
a temperature controlling arrangement attached to the frame structure.

2. An assembly according to claim 1, wherein the middle portion comprises a hollow barrel.

3. An assembly according to claim 1, wherein the light handling system comprises a first light guiding element for providing light to the sample, and a second light guiding element for collecting light scattered off or reflected from the sample.

4. An assembly according to claim 3, wherein the first and second light guiding elements comprise first and second optical fibres, respectively.

5. An assembly according to claim 4, wherein the first and second optical fibres are arranged in an essentially parallel manner along at least part of their lengths.

6. An assembly according to claim 5, wherein the light handling system further comprises a mirror chip arrangement for holding respective end portions of the first and second optical fibres.

7. An assembly according to claim 6, wherein the end portions of the first and second optical fibres are arranged in V-shaped grooves of the mirror chip arrangement.

8. An assembly according to claim 6, wherein the mirror chip arrangement comprises respective reflective surfaces for directing emitted light from the first optical fibre towards the sample, and for directing light scattered off or reflected from the sample towards the second optical fibre.

9. An assembly according to claim 3, wherein the first and second light guiding elements comprise multimode light guiding elements.

10. An assembly according to claim 1, wherein the frame structure comprises a plurality of electrical contact elements.

11. An assembly according to claim 1, wherein the temperature controlling arrangement comprises a heating element and plurality electrical contact pads, each of said plurality of electrical contact pads being adapted to form an electrical connection with an electrical contact element of the frame structure.

12. An assembly according to claim 11, wherein the heating element and the plurality of electrical contact pads form an integral part of the temperature controlling arrangement.

13. A tip portion for an assembly for holding a sample during characterisation of said sample in an electron microscope, the tip portion comprising
a frame structure,
a light handling system attached to the frame structure, and
a temperature controlling arrangement attached to the frame structure.

14. A tip portion according to claim 13, wherein the light handling system comprises a first light guiding element for providing light to the sample, and a second light guiding element for collecting light scattered off or reflected from the sample.

15. A tip portion according to claim 14, wherein the first and second light guiding elements comprise first and second optical fibres, respectively.

16. A tip portion according to claim 15, wherein the first and second optical fibres are arranged in an essentially parallel manner along at least part of their lengths.

17. A tip portion according to claim 16, wherein the light handling system further comprises a mirror chip arrangement for holding respective end portions of the first and second optical fibres.

18. A tip portion according to claim 17, wherein the end portions of the first and second optical fibres are arranged in V-shaped grooves of the mirror chip arrangement.

19. A tip portion according to claim 17, wherein the mirror chip arrangement comprises respective reflective surfaces for directing emitted light from the first optical fibre towards the sample, and for directing light scattered off or reflected from the sample towards the second optical fibre.
